(19) United States
(12) Patent Application Publication
(10) Pub. No.: US 2022/0050124 A1
(43) Pub. Date: Feb. 17, 2022

(54) INERTIAL SENSOR WITH SPLIT ANCHORS AND FLEXURE COMPLIANCE BETWEEN THE ANCHORS

(71) Applicant: NXP USA, Inc., Austin, TX (US)

(72) Inventors: Fengyuan Li, Gilbert, AZ (US); Andrew C McNeil, Chandler, AZ (US)

(21) Appl. No.: 16/994,816

(22) Filed: Aug. 17, 2020

(51) Int. Cl. G01P 15/125

(52) U.S. Cl. CPC G01P 15/125; G01P 2015/0837

(57) ABSTRACT

An inertial sensor includes a movable mass, a torsion element, and a suspension system suspending the movable mass apart from a surface of a substrate. The torsion element is coupled to the movable mass for enabling motion of the movable mass about an axis of rotation in response to a force imposed upon the movable mass in a direction perpendicular to the surface of the substrate. The suspension system includes first and second anchors attached to the substrate and displaced away from the axis of rotation, a beam connected to the movable mass via the torsion element, a first folded spring coupled between the first anchor and a first beam end of the beam, and a second folded spring coupled between the second anchor and a second beam end of the beam.

### TECHNICAL FIELD OF THE INVENTION

The present invention relates generally to microelectromechanical systems (MEMS) devices. More specifically, the present invention relates to a Z-axis MEMS inertial sensor with enhanced offset stability over temperature performance and enhanced mechanical robustness.

### BACKGROUND OF THE INVENTION

Microelectromechanical Systems (MEMS) sensors are widely used in applications such as automotive, inertial guidance systems, household appliances, protection systems for a variety of devices, and many other industrial, scientific, and engineering systems. Such MEMS sensors are used to sense a physical condition such as acceleration, pressure, angular rotation, or temperature, and to provide an electrical signal representative of the sensed physical condition.

Capacitive-sensing MEMS designs are highly desirable for operation in both acceleration and angular rotation environments and in miniaturized devices, due to their relatively low cost. Capacitive accelerometers sense a change in electrical capacitance, with respect to acceleration, to vary the output of an energized circuit. One common form of accelerometer is a two layer capacitive transducer having a “teeter-totter” or “see saw” configuration. This commonly utilized transducer type uses a movable element or plate that rotates under Z-axis acceleration above a substrate. The accelerometer structure can measure two distinct capacitances to determine differential or relative capacitance.

### SUMMARY

Aspects of the disclosure are defined in the accompanying claims.

In a first aspect, there is provided an inertial sensor comprising a movable mass spaced apart from a surface of a substrate; a torsion element coupled to the movable mass and configured to enable motion of the movable mass about an axis of rotation in response to a force imposed upon the movable mass in a direction that is perpendicular to the surface of the substrate; and a suspension system configured to suspend the movable mass apart from the surface of the substrate. The suspension system comprises a first anchor attached to the substrate; a first folded spring having first and second spring ends, the first spring end being coupled to the first anchor; a second anchor attached to the substrate, each of the first and second anchors being displaced away from the axis of rotation; a second folded spring having third and fourth spring ends, the third spring end being coupled to the second anchor; and a beam connected to the movable mass via the torsion element, the beam having first and second beam ends, the first beam end being coupled to the second spring end of the first folded spring, and the second beam end being coupled to the fourth spring end of the second folded spring.

In a second aspect, there is provided an inertial sensor comprising a movable mass spaced apart from a surface of a substrate; a torsion element having first and second ends, the first end being coupled to the movable mass, the torsion element being configured to enable motion of the movable mass about an axis of rotation in response to a force imposed upon the movable mass in a direction that is perpendicular to the surface of the substrate; and a suspension system configured to suspend the movable mass apart from the surface of the substrate. The suspension system comprises a first anchor attached to the substrate; a first folded spring having first and second spring ends, the first spring end being coupled to the first anchor; a second anchor attached to the substrate, each of the first and second anchors being displaced away from the axis of rotation; a second folded spring having third and fourth spring ends, the third spring end being coupled to the second anchor; and a beam connected to the movable mass via the torsion element, the beam having first and second beam ends, the first beam end being coupled to the second spring end of the first folded spring, the second beam end being coupled to the fourth spring end of the second folded spring, the second end of the torsion element being attached to the beam at a midpoint of the beam between the first and second beam ends, and a longitudinal dimension of the beam extends on opposing sides of the axis of rotation, the longitudinal dimension being oriented perpendicular to the axis of rotation.

In a third aspect, there is provided an inertial sensor comprising a movable mass spaced apart from a surface of a substrate; first and second torsion elements coupled to the movable mass and configured to enable motion of the movable mass about an axis of rotation in response to a force imposed upon the movable mass in a direction that is perpendicular to the surface of the substrate; and a suspension system configured to suspend the movable mass apart from the surface of the substrate. The suspension system comprises first, second, third, and fourth anchors attached to the substrate, each of the first, second, third, and fourth anchors being displaced away from the axis of rotation; a first folded spring having first and second spring ends, the first spring end being coupled to the first anchor; a second folded spring having third and fourth spring ends, the third spring end being coupled to the second anchor; a third folded spring having fifth and sixth spring ends, the fifth spring end being coupled to the third anchor; a fourth folded spring having seventh and eighth spring ends, the seventh spring end being coupled to the fourth anchor; a first beam connected to the movable mass via the first torsion element, the first beam having first and second beam ends, the first beam end being coupled to the second spring end of the first folded spring, the second beam end being coupled to the fourth spring end of the second folded spring; and a second beam connected to the movable mass via the second torsion element, the second beam having third and fourth beam ends, the third beam end being coupled to the sixth spring end of the third folded spring, and the fourth beam end being coupled to the eighth spring end of the fourth folded spring, wherein a longitudinal dimension of each of the first and second beams is oriented perpendicular to the axis of rotation.

### BRIEF DESCRIPTION OF THE DRAWINGS

The accompanying figures in which like reference numerals refer to identical or functionally similar elements throughout the separate views, the figures are not necessarily drawn to scale, and which together with the detailed description below are incorporated in and form part of the specification, serve to further illustrate various embodiments and to explain various principles and advantages all in accordance with the present invention.

FIG. 1 shows a plan view of a prior art inertial sensor;

FIG. 2 shows a side view of the prior art inertial sensor;

FIG. 3 shows a side view of the prior art inertial sensor in which a movable mass undergoes tilt in response to warpage of the underlying substrate;

FIG. 4 shows a plan view of an inertial sensor in accordance with an embodiment;

FIG. 5 shows an enlarged partial plan view of the inertial sensor of FIG. 4;

FIG. 6 shows a side view of the inertial sensor of FIG. 4 in which the direction and magnitude of tilt a movable mass is generally averaged out due to a split anchor design in accordance with an embodiment;

FIG. 7 shows a side view of the inertial sensor along section line A-B shown in FIG. 4;

FIG. 8 shows a side view of the inertial sensor along section line A-B shown in FIG. 4 with an adverse effect resulting from process variation; and

FIG. 9 shows a plan view of an inertial sensor in accordance with another embodiment; and

FIG. 10 shows a plan view of an inertial sensor in accordance with another embodiment.

### DETAILED DESCRIPTION

In overview, the present disclosure concerns a microelectromechanical systems (MEMS) inertial sensor with enhanced offset stability over temperature performance and enhanced mechanical robustness under high-g shock environments. More particularly, the inertial sensor has a movable mass that rotates under Z-axis acceleration above a substrate. The inertial sensor includes anchors distributed on both sides of an axis of rotation and flexure compliance between the distributed anchors. The distributed anchor location and the flexure compliance between the anchors may enable the direction and magnitude of tilt of the movable mass due to warpage of the underlying substrate or offset caused by other process variations to be averaged out. Further, the distributed anchor locations and the flexure compliance between the anchors may effectively reduce the maximum principle stress on the movable mass in response to high-g shock environments (e.g., 30,000 g), relative to prior art central anchor designs. As such, the inertial sensor may have enhanced mechanical robustness under high-g shock environments. Still further, the distributed anchor locations and the flexure compliance between the anchors do not impact the torsional stiffness of the torsion elements that enable motion of the movable mass about an axis of rotation, and therefore do not adversely affect the sensitivity of Z-axis sensing of the inertial sensor.

The instant disclosure is provided to further explain in an enabling fashion at least one embodiment in accordance with the present invention. The disclosure is further offered to enhance an understanding and appreciation for the inventive principles and advantages thereof, rather than to limit in any manner the invention. The invention is defined solely by the appended claims including any amendments made during the pendency of this application and all equivalents of those claims as issued.

It should be understood that the use of relational terms, if any, such as first and second, top and bottom, and the like are used solely to distinguish one from another entity or action without necessarily requiring or implying any actual such relationship or order between such entities or actions. Furthermore, some of the figures may be illustrated using various shading and/or hatching to distinguish the different elements produced within the various structural layers. These different elements within the structural layers may be produced utilizing current and upcoming microfabrication techniques of depositing, patterning, etching, and so forth. Accordingly, although different shading and/or hatching may be utilized in the illustrations, the different elements within the structural layers may be formed out of the same material.

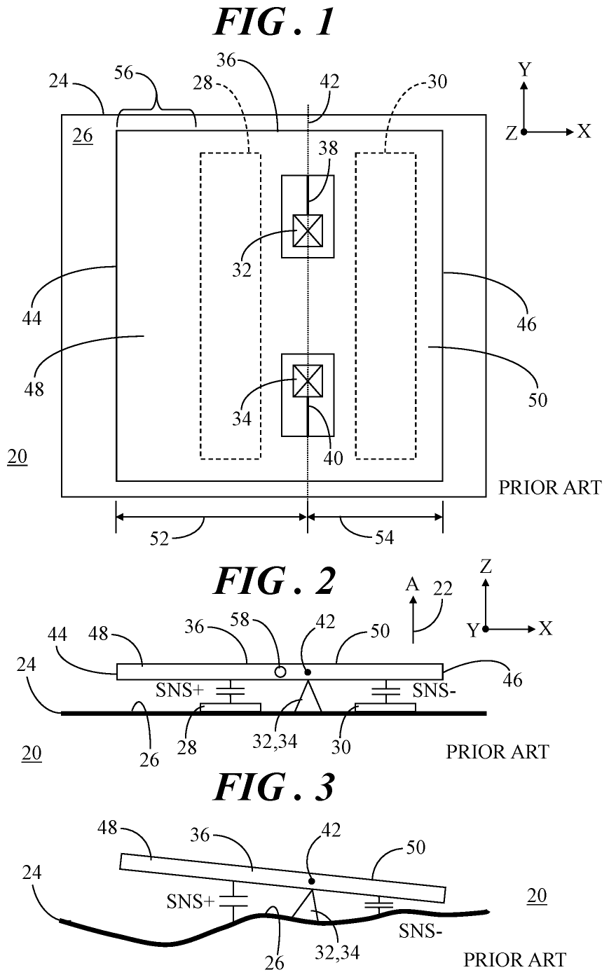

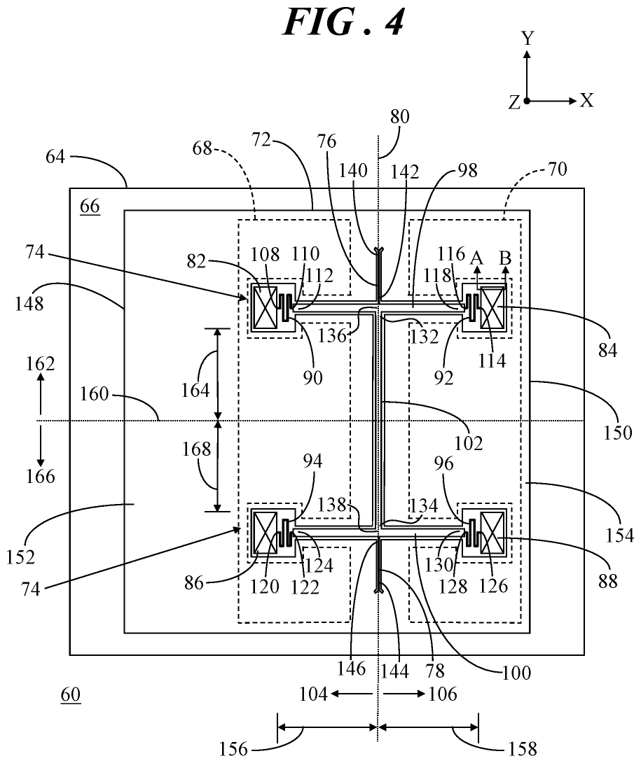

Referring to FIGS. 1-2, FIG. 1 shows a plan view of a prior art inertial sensor 20 and FIG. 2 shows a side view of prior art inertial sensor 20. Inertial sensor 20, in the form of an accelerometer, is adapted to sense Z-axis acceleration, represented by an arrow 22 in FIG. 2, and is constructed as a “teeter-totter” type sensor. Inertial sensor 20 includes a substrate 24 having a surface 26. A first sense element 28 and a second sense element 30 (represented by dashed lines in FIG. 1) are formed on surface 26 of substrate 24. In addition, suspension anchors 32, 34 are formed on surface 26 of substrate 24. A movable mass, referred to herein as a proof mass 36, is positioned in spaced apart relationship above surface 26 of substrate 24. First and second torsion elements 38, 40 interconnect proof mass 36 with suspension anchors 32, 34 so that proof mass 36 is suspended above substrate 24.

Proof mass 36 is adapted for rotational motion in response to acceleration 22 along an axis perpendicular to surface 26 of substrate 24, thus changing its position relative to the underlying first and second sense elements 28, 30. This rotational motion occurs about an axis of rotation 42 positioned between a first end 44 and a second end 46 of proof mass 36. In order to operate as a teeter-totter type accelerometer, a first section 48 of proof mass 36 on one side of axis of rotation 42 is formed with relatively greater mass than a second section 50 on the other side of axis of rotation 42. The greater mass of first section 48 may be created by offsetting axis of rotation 42 such that a first length 52 of first section 48 between axis of rotation 42 and first end 44 of proof mass 36 is greater than a second length 54 of second section 50 between axis of rotation 42 and second end 46 of proof mass 36.

First and second sense elements 28, 30 are symmetrically arranged relative to axis of rotation 42. That is, first and second sense elements 28, 30 are positioned equidistant from axis of rotation 42. The area of first section 48 beyond first sense element 28 to first end 44 is referred to herein as an asymmetric portion 56 of proof mass 34. The presence of asymmetric portion 56 results in the greater mass of first section 48 relative to second section 50. For simplicity, first section 48 of proof mass 36 having the greater mass may alternatively be referred to hereinafter has heavy-end 48 and second section 50 may thus be referred to hereinafter as light-end 50.

Due to the asymmetric configuration of first and second sections 48, 50, proof mass 36 can pivot about axis of rotation 42 in response to Z-axis acceleration 22. Inertial sensor 20 may detect or otherwise measure two distinct capacitances: SNS+ between first section 48 and first sense element 28 and SNS− between second section 50 and second sense element 30. The two capacitances, SNS+ and SNS−, can be used to determine differential or relative capacitance.

In this prior art configuration, suspension anchors 32, 34 and first and second torsion elements 38, 40 are symmetrically arranged relative to axis of rotation 42. More specifically, suspension anchors 32, 34 and first and second torsion elements 38, 40 are aligned with and positioned at axis of rotation 42. However, the greater first length 52 of heavy end 48 relative to second length 54 of light end 50 causes the center of gravity of proof mass 36 to be shifted away from the pivot axis (i.e., axis of rotation 42). As particularly observed in FIG. 2, a center of gravity 58 (denoted by a circle) of proof mass 36 is shifted leftward away from axis of rotation 42. Additionally, a triangle represents suspension anchors 32, 34 located along axis of rotation 42.

FIG. 3 shows a side view of prior art inertial sensor 20 in which the movable mass, i.e., proof mass 36, undergoes tilt in response to warpage of the underlying substrate 24. For purposes of illustration, FIG. 3 shows exaggerated warpage of substrate 24. The warpage of substrate 24 can be caused by the mismatch of the coefficient of thermal expansion (CTE) among the different materials used to form the packaged inertial sensor 20. The CTE of a material describes how the size of an object changes with a change in temperature. In the example of FIG. 3, the warpage of substrate 24 may cause sloping at the location of suspension anchors 32, 34. This sloping of substrate 24 at the anchor locations can determine the direction and magnitude of tilt of proof mass 36. This tilt results in offset between the measured capacitances, SNS+ and SNS−, which can result in measurement error. Even if there is no substrate warpage, offset can be caused by other known and unknown process variations.

Embodiments described below entail a structural configuration of suspension anchors in which the suspension anchors are displaced away from the axis of rotation, referred to herein as a split anchor configuration. In the split anchor configuration, the direction and magnitude of tilt due to substrate warpage and/or process variations is averaged out or otherwise significantly reduced to yield enhanced offset over temperature performance and a mechanically robust design.

Referring now to FIG. 4, FIG. 4 shows a plan view of a MEMS inertial sensor 60 in accordance with an embodiment. Inertial sensor 60, in the form of an accelerometer, is adapted to sense Z-axis acceleration, represented by arrow 22 (FIG. 2), and is constructed as a “teeter-totter” type sensor. Inertial sensor 60 includes a substrate 64 having a surface 66. A first sense element 68 and a second sense element 70 (represented by dashed lines in FIG. 4) are formed on surface 66 of substrate 64. Inertial sensor 60 further includes a movable mass, referred to herein as a proof mass 72, spaced apart from surface 66 of substrate 64, a suspension system 74 configured to suspend proof mass 72 apart from surface 66 of substrate 64, and first and second torsion elements 76, 78 that interconnect proof mass 72 with suspension system 74. First and second torsion elements 76, 78 are configured to enable motion of proof mass 72 about an axis of rotation 80 in response to Z-axis acceleration imposed upon proof mass 72 in a direction perpendicular to surface 66 of substrate 64.

In the illustrated configuration of FIG. 4, suspension system 74 includes first, second, third, and fourth anchors 82, 84, 86, 88, first, second, third, and fourth folded springs 90, 92, 94, 96, first and second beams 98, 100, and a coupler 102. First, second, third, and fourth anchors 82, 84, 86, 88 are attached to substrate 64 and each of first, second, third, and fourth anchors 82, 84, 86, 88 are displaced away from axis of rotation 80. More particularly, first and third anchors 82, 86 are positioned at a first side 104 of axis of rotation 80 and second and fourth anchors 84, 88 are positioned at a second side 106 of axis of rotation 80 opposing first side 102.

First folded spring 90 has first and second spring ends 108, 110, in which first spring end 108 is coupled to first anchor 82 and second spring end 110 is coupled to a first beam end 112 of first beam 98. Second folded spring 92 has third and fourth spring ends 114, 116, in which third spring end 114 is coupled to second anchor 84 and fourth spring end 116 is coupled to a second beam end 118 of first beam 98. Similarly, third folded spring 94 has fifth and sixth spring ends 120, 122, in which fifth spring end 120 is coupled to third anchor 86 and sixth spring end 122 is coupled to a third beam end 124 of second beam 100. And fourth folded spring 96 has seventh and eighth spring ends 126, 128, in which seventh spring end 126 is coupled to fourth anchor 88 and eighth spring end 128 is coupled to a fourth beam end 130 of second beam 100. As such, each of first and second beams 98, 100 extends on opposing sides of axis of rotation to suitably interconnect with respective first, second, third, and fourth folded springs 90, 92, 94, 96.

Coupler 102 is positioned at and aligned with axis of rotation 80. Coupler 102 includes first and second coupler ends 132, 134. A first midpoint 136 of first beam 98 between first and second beam ends 112, 118 is connected to first coupler end 132 and a second midpoint 138 of second beam 100 between third and fourth beam ends 124, 130 is connected to second coupler end 134. Additionally, first torsion element 76 has a first end 140 attached to proof mass 72 and a second end 142 attached to first coupler end 132 of coupler 102. Likewise, second torsion element 78 has a third end 144 coupled to proof mass 72 and a fourth end 146 attached to second coupler end 134 of coupler 102. Accordingly, first and second torsion elements 76, 78 interconnect proof mass 72 with suspension system 74 so that proof mass 72 is suspended above substrate 64.

Proof mass 72 is adapted for rotational motion in response to acceleration 22 (FIG. 2) along an axis perpendicular to surface 66 of substrate 64, thus changing its position relative to the underlying first and second sense elements 68, 70. This rotational motion occurs about rotational axis 80 positioned between a first end 148 and a second end 150 of proof mass 72. In order to operate as a teeter-totter type accelerometer, a first section 152 of proof mass 72 on one side of rotational axis 80 is formed with relatively greater mass than a second section 154 on the other side of rotational axis 80. The greater mass of first section 152 may be created by offsetting rotational axis 80 between first and second ends 148, 150 of proof mass 72 as discussed above.

As mentioned previously, first and third anchors 82, 86 are positioned at first side 104 of axis of rotation and second and fourth anchors 84, 88 are positioned at second side 106 of axis of rotation. In some embodiments, first and third anchors 82, 86 are displaced away from axis of rotation 80 by a first distance 156 and second and fourth anchors 84, 88 are displaced away from axis of rotation 80 by a second distance 158 that is substantially equivalent to first distance 156. Additionally, proof mass 72 is defined by a midline 160 oriented perpendicular to axis of rotation 80. In some embodiments, first and second anchors 82, 84 are positioned at a third side 162 of midline 160 and are displaced away from midline 160 by a third distance 164. Third and fourth anchors 86, 88 are positioned at a fourth side 166 of midline 160 opposing third side 162 and are displaced away from midline 160 by a fourth distance 168 that is substantially equivalent to third distance 164. Thus, in some embodiments, first, second, third, and fourth anchors 82, 84, 86, 88 are symmetrically arranged relative to axis of rotation 80 and midline 160.

In the illustrated example of FIG. 4, first, second, third, and fourth anchors 82, 84, 86, 88 may be pillars set in proximity to first and second sense elements 68, 70. Consequently, first and second sense elements 68, 70 may be suitably shaped to accommodate attachment of first, second, third, and fourth anchors 82, 84, 86, 88 to surface 66 of substrate 64 (as denoted by the irregular shape of the dashed boxes representing first and second sense elements 68, 70). It should be understood that first and second sense elements 68, 70 may be any suitable shape and size. Further, each of first and second sense elements 68, 70 may be formed of multiple individual segments that can be electrically interconnected to yield first and second sense elements 68, 70

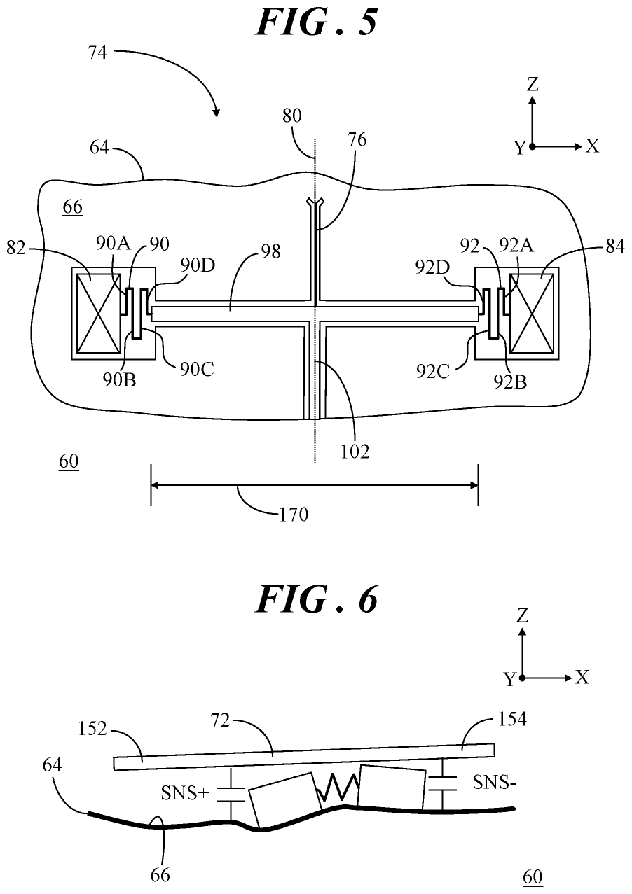

FIG. 5 shows an enlarged partial plan view of inertial sensor 60. In particular, FIG. 5 shows a portion of suspension system 74 that includes first and second anchors 82, 84 and first and second folded springs 90, 92 interconnected via first beam 98 as discussed previously. The following discussion applies equivalently to third and fourth anchors 86, 88, third and fourth folded springs 94, 96, and second beam 100 of suspension system 74.

As shown, first beam 98 extends on opposing sides of axis of rotation 80, and a longitudinal dimension 170 of first beam 98 is oriented perpendicular to axis of rotation 80. First and second anchors 82, 84 reside on opposing sides of axis of rotation, and may thus be considered a split anchor design in lieu of the on-axis, central anchor design of FIG. 1. First folded spring 90 includes at least two spans (e.g., spans 90A, 90B, 90C, 90D) that are connected in sequence and whose directions of extension (i.e., lengths) are parallel to axis of rotation 80. Likewise, second folded spring 92 includes at least two spans (e.g., spans 92A, 92B, 92C, 92D) that are interconnected in sequence and whose directions of extension (i.e., lengths) are also parallel to axis of rotation 80. The compliance of first and second folded springs 90, 92 can be suitably designed by the number of turns (i.e., quantity of spans) as well as the length of the spans. In contrast, first beam 98 is noncompliant relative to first and second folded springs 90, 92.

Referring concurrently to FIGS. 4-6, FIG. 6 shows a side view of inertial sensor 60 in which the direction and magnitude of tilt of proof mass 72 is generally averaged out due to the split anchor design in accordance with an embodiment. In operation, first and second folded springs 90, 92 provide the compliance to “absorb” deformation or movement of anchors 82, 84 due to warpage of the underlying substrate 64. Again, the warpage of substrate 64 is shown in an exaggerated form for illustrative purposes. This substrate warpage may result from a mismatch in the coefficient of thermal expansion (CTE) of the various materials that make up inertial sensor 60. Since first and second folded springs 90, 92 provide the compliance to “absorb” deformation or movement of anchors 82, 84, first beam 98 stays relatively parallel to the plane of surface 66 of substrate 64 under a condition of substrate warpage. Moreover, since first beam 98 stays relatively parallel to the plane of surface 66 of substrate 64 under a condition of substrate warpage, proof mass 72 also stays relatively parallel to the plane of surface 66 of substrate 64.

The direction and magnitude of tilt of proof mass 72 is generally averaged out since the distributed anchors (e.g., first, second, third, and fourth anchors 82, 84, 86, 88) are positioned over a relatively large area and the flexures (e.g., first, second, third, and fourth folded springs 90, 92, 94, 96) between the anchors are compliant. By averaging out, or otherwise reducing the direction and magnitude of tilt of proof mass 72, better offset over temperature performance may be achieved.

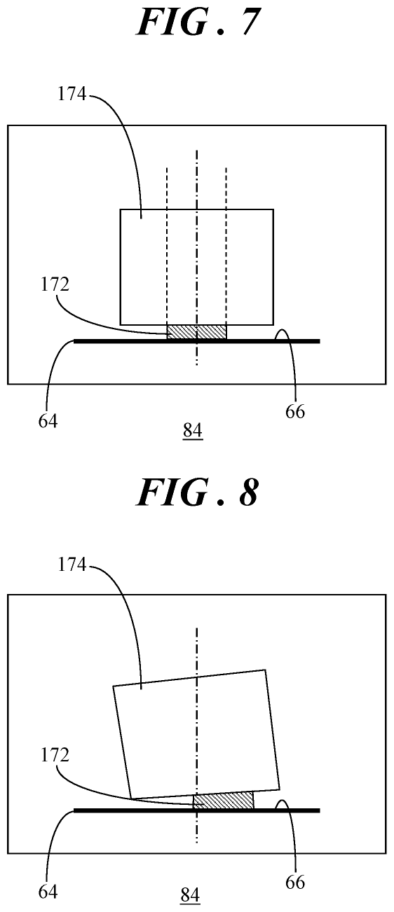

Referring to FIGS. 7-8, FIG. 7 shows a side view of inertial sensor 20 along section line A-B shown in FIG. 4 and FIG. 8 shows a side view of inertial sensor 20 along section line A-B shown in FIG. 4 with an adverse effect resulting from process variation. More particularly, FIGS. 7 and 8 show examples of second anchor 84. In FIGS. 7-8, a connecting material 172 (for example, silicon dioxide) may be used to attach a material layer 174 of second anchor 84 to surface 66 of substrate 64. FIG. 7 demonstrates a “centered” anchor configuration in which connecting material 172 of second anchor 84 is aligned or otherwise formed in its designed location. Conversely, FIG. 8 demonstrates an “off-centered” anchor configuration in which connecting material 172 of second anchor 84 shows misalignment from its designed location.

Offset can be caused by other process variations even if there is no substrate warpage or in addition to substrate warpage. In this example, the misalignment of connecting material 172 and the polysilicon material layer 174 could result in asymmetric deformation caused by CTE mismatch between connecting material 172 and polysilicon material layer 174 of second anchor 84. With the distributed anchor configuration of first, second, third, and fourth anchors 82, 84, 86, 88 (FIG. 4), proof mass 72 (FIG. 4) may experience significantly less deformation due to the compliance in first, second, third, and fourth folded springs 90, 92, 94, 96.

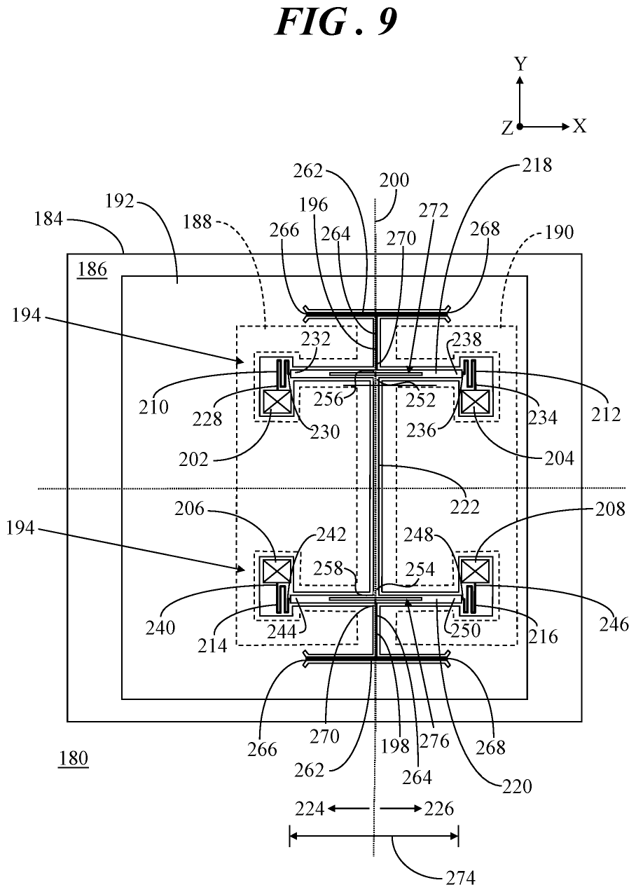

FIG. 9 shows a plan view of an inertial sensor 180 in accordance with another embodiment. Inertial sensor 180 is also constructed as a “teeter-totter” type sensor. Inertial sensor 180 includes a substrate 184 having a surface 186. A first sense element 188 and a second sense element 190 (represented by dashed lines in FIG. 9) are formed on surface 186 of substrate 184. Inertial sensor 180 further includes a movable mass, referred to herein as a proof mass 192, spaced apart from surface 186 of substrate 184, a suspension system 194 configured to suspend proof mass 192 apart from surface 186 of substrate 184, and first and second torsion elements 196, 198 that interconnect proof mass 192 with suspension system 194. First and second torsion elements 196, 198 are configured to enable motion of proof mass 192 about an axis of rotation 200 in response to Z-axis acceleration imposed upon proof mass 192 in a direction that is perpendicular to surface 186 of substrate 184.

Suspension system 194 includes first, second, third, and fourth anchors 202, 204, 206, 208, first, second, third, and fourth folded springs 210, 212, 214, 216, first and second beams 218, 220, and a coupler 222. First, second, third, and fourth anchors 202, 204, 206, 208 are attached to substrate 184 and each of first, second, third, and fourth anchors 202, 204, 206, 208 is displaced away from axis of rotation 200. More particularly, first and third anchors 202, 206 are positioned at a first side 224 of axis of rotation 200 and second and fourth anchors 204, 208 are positioned at a second side 226 of axis of rotation 200 opposing first side 224.

First folded spring 210 has first and second spring ends 228, 230, in which first spring end 228 is coupled to first anchor 202 and second spring end 230 is coupled to a first beam end 232 of first beam 218. Second folded spring 212 has third and fourth spring ends 234, 236, in which third spring end 234 is coupled to second anchor 204 and fourth spring end 236 is coupled to a second beam end 238 of first beam 218. Similarly, third folded spring 214 has fifth and sixth spring ends 240, 242, in which fifth spring end 240 is coupled to third anchor 206 and sixth spring end 242 is coupled to a third beam end 244 of second beam 220. And fourth folded spring 216 has seventh and eighth spring ends 246, 248, in which seventh spring end 246 is coupled to fourth anchor 208 and eighth spring end 248 is coupled to a fourth beam end 250 of second beam 220. As such, each of first and second beams 218, 220 extends on opposing sides of axis of rotation 200 to suitably interconnect with respective first, second, third, and fourth folded springs 210, 212, 214, 216.

In the illustrated embodiment, the design of first, second, third, and fourth folded springs 210, 212, 214, 216 of inertial sensor 180 differs from first, second, third, and fourth folded springs 90, 92, 94, 96 (FIG. 4) of inertial sensor 60 (FIG. 4). The configuration of FIG. 9, enables placement of first, second, third, and fourth anchors 202, 204, 206, 208 closer to axis of rotation 200 when there is limited space in the X-direction of proof mass 192.

Coupler 222 is positioned at and aligned with axis of rotation 200. Coupler 222 includes first and second coupler ends 252, 254. A first midpoint 256 of first beam 218 between first and second beam ends 232, 238 is connected to first coupler end 252 and a second midpoint 258 of second beam 220 between third and fourth beam ends 244, 250 is connected to second coupler end 254.

In the illustrated embodiment, each of first and second torsion elements 196, 198 is a “T-shaped” structure having a beam 262 oriented perpendicular to axis of rotation 200 and a beam 264 coupled to a midpoint of beam 262 and oriented parallel to axis of rotation 200. Opposing ends 266, 268 of beam 262 of first torsion element 196 are attached to proof mass 192 and an end 270 of beam 264 of first torsion element 196 is attached to first coupler end 252 of coupler 222. Likewise, opposing ends 266, 268 of beam 262 of second torsion element 198 are attached to proof mass 192 and end 270 of beam 264 of second torsion element 198 is attached to second coupler end 254 of coupler 222. Accordingly, first and second torsion elements 196, 198 interconnect proof mass 192 with suspension system 194 so that proof mass 192 is suspended above substrate 184.

In the illustrated embodiment, first beam 218 has an elongate opening 272 aligned with a longitudinal dimension 274 of first beam 218 and centered between first and second beam ends 232, 238. Likewise, second beam 220 has an elongate opening 276 aligned with longitudinal dimension 274 of second beam 220 and centered between third and fourth beam ends 244, 250. Thus, on opposing longitudinal edges of elongate openings 272, 276, the remaining material portions of each of first and second beams 218, 220 is relatively thinner, thus more compliant then the remainder of first and second beams 218, 220. The combination of the “T-shaped” structure of each of first and second torsion elements 196, 198 and the compliancy gained in first and second beams 218, 220 by the presence of elongate openings 272, 276 may provide additional compliance in the vertical direction (e.g., parallel to the Z-axis) to provide some stress relief during a high-g shock event. Thus, such a structural configuration may provide inertial sensor 180 with enhanced protection from damage during a high-g shock event.

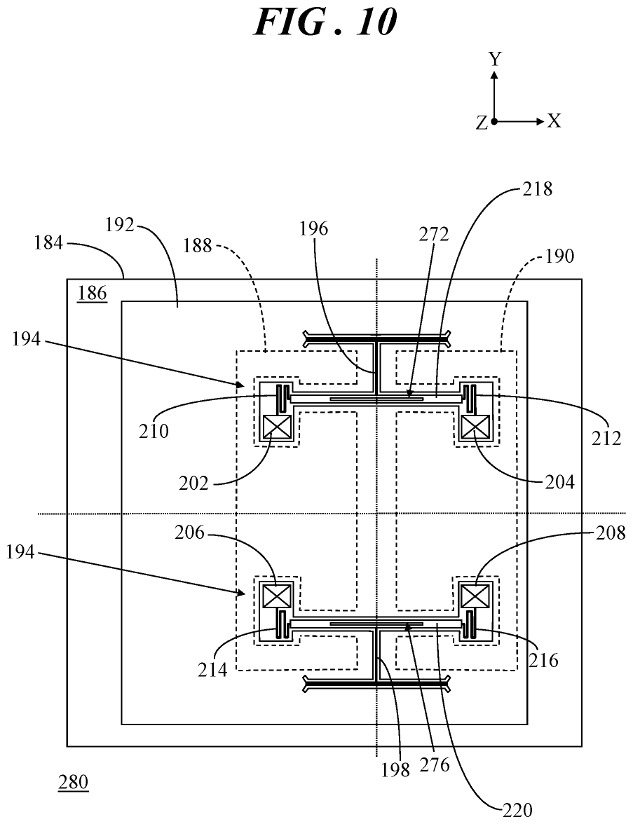

FIG. 10 shows a plan view of an inertial sensor 280 in accordance with another embodiment. Inertial sensor 280 is similar to inertial sensor 180 of FIG. 9. Thus, the same reference numerals used in FIG. 9 will also be utilized in FIG. 10. As such, inertial sensor 280 includes substrate 184 having surface 186 with first and second sense elements 188, 190 formed on surface 186 of substrate 184. Inertial sensor 280 further includes proof mass 192, suspension system 194 configured to suspend proof mass 192 apart from surface 186 of substrate 184, and first and second torsion elements 196, 198 that interconnect proof mass 192 with suspension system 194. Suspension system 194 again includes first, second, third, and fourth anchors 202, 204, 206, 208, first, second, third, and fourth folded springs 210, 212, 214, 216, and first and second beams 218, 220. However, in contrast to inertial sensor 180 (FIG. 9), inertial sensor 280 does not include a coupler (e.g., coupler 222, FIG. 9) interconnecting first and second beams 218, 220 of inertial sensor 280. Such a configuration may simplify manufacturing of suspension system 194 without compromising the ability of suspension system 194 to enable improved offset performance and enhanced protection from damage during a high-g shock event.

The configurations of the suspension systems of inertial sensors 60 (FIG. 4), 180 (FIGS. 9), and 280 (FIG. 10) can vary from that shown. For example, a single pair of anchors, a single pair of folded springs, and one interconnecting beam may be sufficient to suspend a proof mass above a surface of a substrate in some embodiments. Other embodiments may include more than the illustrated four anchors, four folded springs, and two beams.

Embodiments described herein entail microelectromechanical systems (MEMS) inertial sensors with enhanced offset stability over temperature performance and enhanced mechanical robustness under high-g shock environments. More particularly, an inertial sensor has a movable mass that rotates under Z-axis acceleration above a substrate. The inertial sensor includes anchors distributed on both sides of an axis of rotation and flexure compliance between the distributed anchors. The distributed anchor location and the flexure compliance between the anchors may enable the direction and magnitude of tilt of the movable mass due to warpage of the underlying substrate or offset caused by other process variations to be averaged out. Further, the distributed anchor locations and the flexure compliance between the anchors may effectively reduce the maximum principle stress on the movable mass in response to high-g shock environments (e.g., 30,000 g), relative to prior art central anchor designs. As such, the inertial sensor may have enhanced mechanical robustness under high-g shock environments. Still further, the distributed anchor locations and the flexure compliance between the anchors do not impact the torsional stiffness of the torsion elements that enable motion of the movable mass about an axis of rotation, and therefore do not adversely affect the sensitivity of Z-axis sensing of the inertial sensor.

This disclosure is intended to explain how to fashion and use various embodiments in accordance with the invention rather than to limit the true, intended, and fair scope and spirit thereof. The foregoing description is not intended to be exhaustive or to limit the invention to the precise form disclosed. Modifications or variations are possible in light of the above teachings. The embodiment(s) was chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims, as may be amended during the pendency of this application for patent, and all equivalents thereof, when interpreted in accordance with the breadth to which they are fairly, legally, and equitably entitled.

1. An inertial sensor comprising:
a movable mass spaced apart from a surface of a substrate;
a torsion element coupled to the movable mass and configured to enable motion of the movable mass about an axis of rotation in response to a force imposed upon the movable mass in a direction that is perpendicular to the surface of the substrate; and
a suspension system configured to suspend the movable mass apart from the surface of the substrate, the suspension system comprising:
a first anchor attached to the substrate;
a first folded spring having first and second spring ends, the first spring end being coupled to the first anchor;
a second anchor attached to the substrate, each of the first and second anchors being displaced away from the axis of rotation;
a second folded spring having third and fourth spring ends, the third spring end being coupled to the second anchor;
a beam connected to the movable mass via the torsion element, the beam having first and second beam ends, the first beam end being coupled to the second spring end of the first folded spring, and the second beam end being coupled to the fourth spring end of the second folded spring; and
a coupler positioned at and aligned with the axis of rotation, wherein a midpoint of the beam between the first and second beam ends is connected to the coupler, and the torsion element has a first end attached to the movable mass and a second end attached to the coupler;
wherein the first end of the torsion element comprises a longitudinal member oriented perpendicular to the axis of rotation that extends across the axis of rotation, the longitudinal member having first and second ends coupled to the movable mass.

2. The inertial sensor of claim 1 wherein the torsion element has a first end attached to the movable mass and a second end attached to the beam at a midpoint of the beam between the first and second beam ends.

3. (canceled)

4. The inertial sensor of claim 1 wherein a longitudinal dimension of the beam extends on opposing sides of the axis of rotation, the longitudinal dimension being oriented perpendicular to the axis of rotation.

5. The inertial sensor of claim 1 wherein:
the first and second anchors are positioned at opposing sides of the axis of rotation;
the first anchor is displaced away from the axis of rotation by a first distance; and
the second anchor is displaced away from the axis of rotation by a second distance that is substantially equivalent to the first distance.

6. The inertial sensor of claim 1 wherein the beam is noncompliant relative to the first and second folded springs. (Original) The inertial sensor of claim 1 wherein the beam has an elongate opening aligned with a longitudinal dimension of the beam, the elongate opening being centered between the first and second beam ends.

8. The inertial sensor of claim 1 wherein each of the first and second folded springs has at least two spans whose directions of extension are parallel to the axis of rotation.

9. The inertial sensor of claim 1 wherein:
the torsion element is a first torsion element;
the beam is a first beam;
the inertial sensor further comprises a second torsion element coupled to the movable mass and configured to enable motion of the movable mass about the axis of rotation; and
the suspension system further comprises:
a third anchor attached to the substrate;
a third folded spring having fifth and sixth spring ends, the fifth spring end being coupled to the third anchor;
a fourth anchor attached to the substrate, each of the third and fourth anchors being displaced away from the axis of rotation;
a fourth folded spring having seventh and eighth spring ends, the seventh spring end being coupled to the fourth anchor; and
a second beam connected to the movable mass via the second torsion element, the second beam having third and fourth beam ends, the third beam end being coupled to the fifth spring end of the third folded spring, and the fourth beam end being coupled to the eighth spring end of the fourth folded spring.

10. The inertial sensor of claim 9 further comprising a coupler positioned at and aligned with the axis of rotation, the coupler having first and second coupler ends, wherein:
a first midpoint of the first beam between the first and second beam ends is connected to the first coupler end;
a second midpoint of the second beam between the third and fourth beam ends is connected to the second coupler end;
the first torsion element has a first end attached to the movable mass and a second end attached to the first coupler end; and
the second torsion element has a third end attached to the movable mass and a fourth end attached to the second coupler end.

11. The inertial sensor of claim 9 wherein:
the first and third anchors are positioned at a first side of the axis of rotation and displaced away from the axis of rotation by a first distance; and
the second and fourth anchors are positioned at second side of the axis of rotation opposing the first side and are displaced away from the axis of rotation by a second distance that is substantially equivalent to the first distance.

12. The inertial sensor of claim 11 wherein the movable mass is defined by a midline oriented perpendicular to the axis of rotation and parallel to the surface of the substrate, and wherein:
the first and second anchors are positioned at a third side of the midline and displaced away from the midline by a third distance; and
the third and fourth anchors are positioned at a fourth side of the midline opposing the third side and are displaced away from the midline by a fourth distance that is substantially equivalent to the third distance.

13. An inertial sensor comprising:
a movable mass spaced apart from a surface of a substrate;
a torsion element having first and second ends, the first end being coupled to the movable mass, the torsion element being configured to enable motion of the movable mass about an axis of rotation in response to a force imposed upon the movable mass in a direction that is perpendicular to the surface of the substrate, wherein:
the first end of the torsion element includes a longitudinal member oriented perpendicular to the axis of rotation that extends across the axis of rotation, the longitudinal member having first and second ends coupled to the movable mass; and
the second end of the torsion element includes a perpendicular member having a proximal end and a distal end, the proximal end being coupled to a midpoint of the longitudinal member and extending from the longitudinal member in a direction parallel to the axis of rotation; and
a suspension system configured to suspend the movable mass apart from the surface of the substrate, the suspension system comprising:
a first anchor attached to the substrate;
a first folded spring having first and second spring ends, the first spring end being coupled to the first anchor;
a second anchor attached to the substrate, each of the first and second anchors being displaced away from the axis of rotation;
a second folded spring having third and fourth spring ends, the third spring end being coupled to the second anchor; and
a beam connected to the movable mass via the distal end of the perpendicular member of the torsion element, the beam having first and second beam ends, the first beam end being coupled to the second spring end of the first folded spring, the second beam end being coupled to the fourth spring end of the second folded spring, the second end of the torsion element being attached to the beam at a midpoint of the beam between the first and second beam ends, and a longitudinal dimension of the beam extends on opposing sides of the axis of rotation, the longitudinal dimension being oriented perpendicular to the axis of rotation.

14. (canceled)

15. The inertial sensor of claim 13 wherein:
the first and second anchors are positioned at opposing sides of the axis of rotation;
the first anchor is displaced away from the axis of rotation by a first distance; and
the second anchor is displaced away from the axis of rotation by a second distance that is substantially equivalent to the first distance.

16. The inertial sensor of claim 13 wherein the beam is noncompliant relative to the first and second folded springs.

17. An inertial sensor comprising:
a movable mass spaced apart from a surface of a substrate;
first and second torsion elements coupled to the movable mass and configured to enable motion of the movable mass about an axis of rotation in response to a force imposed upon the movable mass in a direction that is perpendicular to the surface of the substrate, wherein each of the first and second torsion elements includes:
a longitudinal member oriented perpendicular to the axis of rotation that extends across the axis of rotation, the longitudinal member having first and second ends coupled to the movable mass; and
a perpendicular member having a proximal end and a distal end, wherein the proximal end is coupled to a midpoint of the longitudinal member and extends from the longitudinal member in a direction parallel to the axis of rotation; and
a suspension system configured to suspend the movable mass apart from the surface of the substrate, the suspension system comprising:
first, second, third, and fourth anchors attached to the substrate, each of the first, second, third, and fourth anchors being displaced away from the axis of rotation;
a first folded spring having first and second spring ends, the first spring end being coupled to the first anchor;
a second folded spring having third and fourth spring ends, the third spring end being coupled to the second anchor;
a third folded spring having fifth and sixth spring ends, the fifth spring end being coupled to the third anchor;
a fourth folded spring having seventh and eighth spring ends, the seventh spring end being coupled to the fourth anchor;
a first beam connected to the movable mass via the distal end of the perpendicular beam of the first torsion element, the first beam having first and second beam ends, the first beam end being coupled to the second spring end of the first folded spring, the second beam end being coupled to the fourth spring end of the second folded spring; and
a second beam connected to the movable mass via the distal end of the perpendicular member of the second torsion element, the second beam having third and fourth beam ends, the third beam end being coupled to the sixth spring end of the third folded spring, and the fourth beam end being coupled to the eighth spring end of the fourth folded spring, wherein a longitudinal dimension of each of the first and second beams is oriented perpendicular to the axis of rotation.

18. The inertial sensor of claim 17 further comprising a coupler positioned at and aligned with the axis of rotation, the coupler having a first and second coupler ends, wherein:
a first midpoint of the first beam between the first and second beam ends is connected to the first coupler end;
a second midpoint of the second beam between the third and fourth beam ends is connected to the second coupler end;
the first torsion element has a first end attached to the movable mass and a second end attached to the first coupler end; and
the second torsion element has a third end attached to the movable mass and a fourth end attached to the second coupler end.

19. The inertial sensor of claim 17 wherein:
the first and third anchors are positioned at a first side of the axis of rotation and displaced away from the axis of rotation by a first distance; and
the second and fourth anchors are positioned at second side of the axis of rotation opposing the first side and are displaced away from the axis of rotation by a second distance that is substantially equivalent to the first distance.

20. The inertial sensor of claim 19 wherein the movable mass is defined by a midline oriented perpendicular to the axis of rotation and parallel to the surface of the substrate wherein:
the first and second anchors are positioned at a third side of the midline and displaced away from the midline by a third distance; and
the third and fourth anchors are positioned at a fourth side of the midline opposing the third side and are displaced away from the midline by a fourth distance that is substantially equivalent to the third distance.

21. The inertial sensor of claim 13,
wherein the beam has an elongate opening aligned with a longitudinal dimension of the beam, the elongate opening being centered between the first and second beam ends.

22. The inertial sensor of claim 17,
wherein the first beam has an elongate opening aligned with a longitudinal dimension of the beam, the elongate opening being centered between the first and second beam ends; and
wherein the second beam has an elongate opening aligned with a longitudinal dimension of the second beam, the elongate opening being centered between the third and fourth beam ends.
